(19) United States
(12) Patent Application Publication
(10) Pub. No.: US 2025/0371211 A1
(43) Pub. Date: Dec. 4, 2025

(54) SYSTEMS AND METHODS FOR SIMULATING WORK SITE OPERATIONS USING A WIRELESS-BASED TRACKING SYSTEM

(71) Applicant: Federal Express Corporation, Memphis, TN (US)

(72) Inventors: Neal TUCKER, Olathe, KS (US); Cameron A. PASCHKE, Harrison, AR (US); Trenton C. FOX, Harrison, AR (US)

(21) Appl. No.: 18/733,010

(22) Filed: Jun. 4, 2024

(51) Int. Cl. G06F 30/20; G06Q 10/08; G06Q 50/163

(52) U.S. Cl. CPC G06F 30/20; G06Q 10/08; G06Q 50/163

(57) ABSTRACT

A system for simulating an operational scenario on a work site using a wireless-based tracking system includes at least one processor and at least one non-transitory memory storing instructions. A method thereof includes steps of generating a virtual representation of a work site, determining at least one output and a target for each of the output, determining a number of object transport vehicles and antenna placements, generating virtual tags, simulating a movement of the plurality of virtual tags for the outputs, wherein the virtual tags are moved with the object transport vehicles and tracked by the antennas, iteratively adjusting each of the placements of the antennas to optimize output towards the targets, and providing optimized placements of antennas to an interface.

### TECHNICAL FIELD

The present disclosure relates generally to the design and optimization of work sites, such as warehouses, distribution centers, and manufacturing facilities. More particularly, the invention pertains to methods and systems for simulating and optimizing various factors affecting work site operations to enhance efficiency, safety, and productivity.

### BACKGROUND

Work site design plays a crucial role in the overall performance and functionality of industrial facilities. Traditional approaches to work site design often rely on manual processes, trial and error methodologies, and limited consideration of dynamic operational factors. These conventional methods frequently result in suboptimal layouts, inefficient workflows, increased safety risks, and unnecessary operational costs.

With the advancement of technology and the growing complexity of modern industrial operations, there is a pressing need for more sophisticated approaches to work site design. Such approaches should incorporate advanced simulation techniques, real-time data analysis, and optimization algorithms to create highly efficient and adaptable work environments.

Existing solutions in the field of work site design often lack the capability to comprehensively evaluate the interplay of various factors influencing operational performance. These factors include, but are not limited to, the number and types of equipment (e.g., forklifts, conveyors), layout and dimensions of docks and storage areas, dimensions and placement of aisles and pathways, placement of RFID antennas, amount of freight processed, and traffic flow patterns.

Furthermore, conventional work site design methods typically do not account for the dynamic nature of industrial operations, such as fluctuating demand, changing inventory levels, and evolving technology. As a result, work sites designed using these approaches may struggle to accommodate evolving operational requirements and may require costly retrofitting or redesign efforts.

### SUMMARY

The present disclosure includes a method and system that can accurately simulate and optimize work site designs by considering a comprehensive set of factors, including equipment specifications, layout constraints, operational dynamics, and performance objectives. Such a solution would enable industrial stakeholders to design work sites that are not only efficient and safe but also adaptable to changing operational needs and future advancements in technology.

The present disclosure provides a method and system for optimizing work site design through advanced simulation and optimization techniques. By leveraging real-time data, predictive modeling, and optimization algorithms, the disclosed methods enable industrial stakeholders to design and evaluate work sites that maximize operational efficiency, minimize risks, and facilitate seamless workflows.

Specifically, one aspect of the present disclosure is directed to a system for simulating an operational scenario on a work site using a wireless-based tracking system comprising at least one processor and at least one non-transitory memory storing instructions, when the instructions are executed by the at least processor, the at least one processor perform steps of generating a virtual representation of a work site, the work site comprising at least one door and a plurality of zones, determining at least one output and a target for each of the at least one output, generating a plurality of virtual tags based on user inputs, determining a first number of object transport vehicles on the work site, determining placements of a second number of antennas on the virtual representation, wherein the antennas collectively cover at least a part of the work site and are configured to receive signals from the first number of object transport vehicles and the plurality of virtual tags in the covered part of the work site, providing the virtual representation, the plurality of virtual tags, the at least one output, the target of each of the at least one output, the placements of the second number of antennas, and the first number of object transport vehicles to the at least one processor, simulating the movement of the plurality of virtual tags for the at least one output, wherein the plurality of virtual tags are moved with the at least one of the first number of object transport vehicles and tracked by the antennas, iteratively adjusting each of the placements of the second number of antennas to optimize at least one output towards the targets of the at least one output, and providing optimized placements for each of the placements of second number of antennas to an interface.

Another aspect of the present disclosure is directed to a method of simulating an operational scenario on a work site using a wireless-based tracking system comprising at least one processor, the method comprising generating a virtual representation of a work site, the work site comprising at least one door and a plurality of zones, determining at least one output and a target for each of the at least one output, generating a plurality of virtual tags based on user inputs, determining a first number of object transport vehicles on the work site, determining placements of a second number of antennas on the virtual representation, wherein the antennas collectively cover at least a part of the work site and are configured to receive signals from the first number of object transport vehicles and the plurality of virtual tags in the covered part of the work site, providing the virtual representation, the plurality of virtual tags, the at least one output, the target of each of the at least one output, the placements of the second number of antennas, and the first number of object transport vehicles to the at least one processor, simulating the movement of the plurality of virtual tags for the at least one output, wherein the plurality of virtual tags are moved with the at least one of the first number of object transport vehicles and tracked by the antennas, iteratively adjusting each of the placements of the second number of antennas to optimize at least one output towards the targets of the at least one output, and providing optimized placements for each of the placements of second number of antennas to an interface. Other systems and methods are also discussed herein.

### BRIEF DESCRIPTION OF THE DRAWINGS

FIG. 1 is an illustration of a warehouse, consistent with embodiments of this disclosure.

FIG. 2 is a schematic block diagram illustrating an embodiment of a system for simulating the operation of a warehouse, consistent with embodiments of this disclosure.

FIG. 3 is a schematic block diagram illustrating an embodiment of a method for simulating the operation of a warehouse, consistent with embodiments of this disclosure.

### DETAILED DESCRIPTION

The following detailed description refers to the accompanying drawings. Wherever possible, the same reference numbers are used in the drawings and the following description to refer to the same or similar parts. While several illustrative embodiments are described herein, modifications, adaptations and other implementations are possible. For example, substitutions, additions, or modifications may be made to the components and steps illustrated in the drawings, and the illustrative methods described herein may be modified by substituting, reordering, removing, or adding steps to the disclosed methods. Accordingly, the following detailed description is not limited to the disclosed embodiments and examples. Instead, the proper scope of the invention is defined by the appended claims.

Embodiments of the present disclosure are directed to systems and methods configured for simulating operational scenarios on a work site and optimizing various factors affecting work site operations using a wireless-based tracking system to enhance efficiency, safety, and productivity. In some embodiments, the operational scenarios may include real-world situations that an operating work site may encounter. Such scenarios may be defined by operation factors, such as rates of objects incoming to the work site, rates of objects outgoing from the work site, number of operating object transporter,

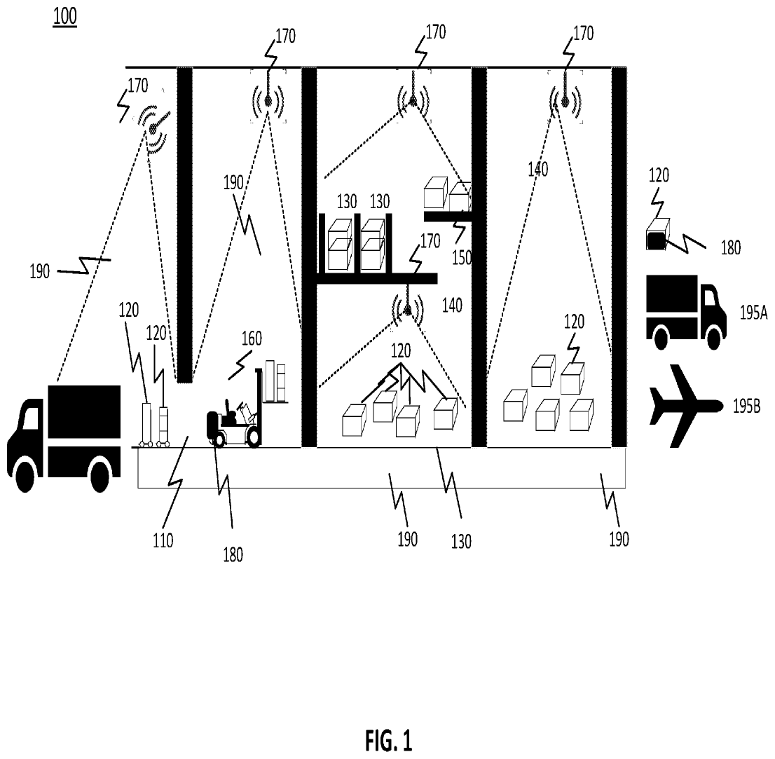

FIG. 1 is an illustration of a warehouse 100, consistent with embodiments of this disclosure. A warehouse is a space or facility designed for storage of goods, materials, merchandise, and other items. It serves as a central point in the supply chain where products or freights are temporarily held before they are shipped to retailers, wholesalers, or directly to customers. While using a warehouse as an example, the disclosed systems and methods may be generally applicable in a work site of different environment settings where objects (e.g., freight) are stored, organized, reorganized, loaded, and/or unloaded. In some embodiments, the warehouse 100 and its details are electronically stored for simulation purposes; embodiments including these aspects are further discussed below.

In some embodiments, the warehouse 100 may have at least one door 110 for receiving and putting away freight 120. In some embodiments, the warehouse 100 may have separate doors 110 for receiving freight 120 and putting away freight 120. In some embodiments, the warehouse 100 may have multiple areas. The multiple areas may be divided or subdivided based on function or location. For example, the warehouse 100 may have a loading/unloading area, corridor, storage area, transitioning area, etc. A storage area may be further subdivided into multiple numbered sub-area, or may be further subdivided into sub-areas for different type of freight, e.g., pallet area, machinery area, refrigerated area, area with environmental control (e.g., temperature and/or humidity control), etc.

In some embodiments, the warehouse 100 may have a plurality of storage bays 130. Each of the plurality of storage bays 130 may have at least one level 140. In other words, each storage bays 130 may be able to keep freight 120 stacked. In some embodiments, multiple pieces of freight 120 may be stacked in a same storage bay 130 on different shelves 150. In some embodiments, multiple pieces of freight 120 may stack on each other without shelves 150, for example, one freight 120 may stack on another freight 120 directly with their pallets on.

In some embodiments, the work site may have a layout of an n-point polygon. In some embodiments, representing a work site as an n-point polygon may capture complex work site shapes. For example, some work sites may have a T shape or H shape plan, or have portions of the site in a non-rectangle shape, e.g., having 15 degree angles. These complex shapes may all fit to an n-point polygon. In some embodiments, having a system that supports n-point polygon layouts may provide the algorithm maximum versatility.

In some embodiments, the ceiling height may follow a linear slope from the center of the n-point polygon to each of the edges of the n-point polygon. In some embodiments, the ceiling height may be calculated at any given location. In some embodiments, the ceiling height may dictate tag reader 170 drop mount, which may determine tag reader 170 installation height, which will be further discussed below.

In some embodiments, freight 120 may refer to goods and cargo that are being stored, handled, and transported in, to, or from the warehouse 100. In some embodiments, freight 120 may be palletized goods, loose cartons or boxes, bulk goods, barrels, drums, crates, rolls, coils, caged goods, or the like. In some embodiments, freight 120 may be a machinery, cars, trucks, or other vehicles or heavy machines. In this disclosure, freight 120 may be generally referred to as “objects” being tracked.

In some embodiments, the warehouse 100 may have a plurality of object transport vehicles 160 operating in the warehouse 100. An object transport vehicle 160 is a moving vehicle with the capability to carry multiple pieces of freight with it. For example, an object transport vehicle 160 may be a forklift, a pallet jack (i.e., hand trucks,) an automated guided vehicle (AGV), a tow tractor, a tugger, a reach truck, a cart (i.e., push cart, a shelving cart,) a dolly, a scissor lift, a crane system (e.g., a bridge crane or a gantry crane,) a tilt truck, or a robotic transporting system.

In some embodiments, the warehouse 100 may have its space divided into zones. In some embodiments, the zones may be identical in size and shape, except on the perimeter of the warehouse 100 where the boundaries of the warehouse 100 prohibits so. In some embodiments, the zones may be defined by two sets of parallel lines, the lines from one group being perpendicular to the lines from the other group of lines, therefore dividing the warehouse 100 into grids. Each of the zones may be identified by a set of coordinates. In some embodiments, the freight 120 may be organized next to each other on the floor of the warehouse 100 so no shelves 150 is needed. In such case, a top view of the warehouse floor (i.e., a floor plan or floor map) may be sufficient to display and monitor the locations of freight 120 and object transport vehicle 160. In some embodiments, users may refer to zones as an alternative of coordinates for the purposes of locating tags (e.g., actual tags, virtual tags, vehicle tags, virtual vehicle tags) and/or communicating the locations of the tags between subsystems and between the system and user. In some embodiments, users and the system may use zones as a measurement of distance because the zones are in most cases identical in size and shape.

In some embodiments, the warehouse 100 may have a plurality of tag readers 170 installed in or near the warehouse 100. Tag readers 170 may be antennas, sensors, or any signal receivers that may actively or passively obtain or receive information stored in a tag. In some embodiments, the installation locations of tag readers 170 may align with the zones of the warehouse. For example, the installation locations of tag readers 170 within one zone are identical to the installation locations of tag readers 170 within other zones. In some embodiments, the number of the tag readers 170 installed within each zone is the same, and their installation locations within each zone might be different to accommodate the building structure and constraints of each zone. In some embodiments, a processor (e.g., processor 210) may calculate the installation height of a specific tag reader 170 by using the ceiling height at the installation location subtracting a tag reader installation drop mount height. In some embodiments, as discussed above, the ceiling height may be calculated by applying the specific installation location to the n-side polygon work site plan and the linear slope. In some embodiments, a drop mount height is the installation mount height, measuring from the ceiling or installation mounting point down towards the floor. In some embodiments, the drop mount height may be easy to use for installation workers.

In some embodiments, a tag 180 may be a device or object that contains information and is equipped with a unique identifier. The unique identifier may distinguish itself from other tags 180 in the system. In some embodiments, a tag 180 may have a memory component that stores data, which may include information such as the unique identifier (e.g., an identification number) and other relevant information associated with the tag 180. In some embodiments, the tag 180 may be a passive tag, i.e., the tag does not have an internal power source and rely on the energy provided by the tag reader 170 during communication with the tag reader 170. In some embodiments, the tag 180 may be an active tag, i.e., the tag has its own power source (e.g., battery) to actively transmit data to the tag reader 170. An active tag can generally operate at greater distances than passive tags. Some tag brands, for example, include Avery Dennison/Smartrack, Beontag/Confidex, Nam Viet, Checkpoint, Omni-ID, etc.

In some embodiments, tag 180 may be operative in different frequencies in different ranges. In some embodiments, tag 180 may encode different information for different frequencies. In some embodiments, the specific frequencies tag 180 is operative in may be for determined by the system administrators and tag readers 170. For example, tag 180 may be operative in the Ultra-high frequency (UHF) range to allow tracking by tag reader 170; tag 180 may be operative in the Low-frequency (LF) range to allow scanning by a user with a handheld device. In some embodiments, operating frequencies may dictate a reading range of the tag reader 170. In some embodiments, depending on the frequencies tag 180 being operative in, processor (e.g., processor 210) may calculate a reading range for simulation purposes. That is, depending on operative frequencies of tag 180, processor (e.g., processor 210) may calculate a reading range and apply the calculated reading range in determining tag reader 170 placements.

In some embodiments, the tags 180 in the disclosed system may be passive or active, or a combination of passive tags and active tags. In some embodiments, the tags 180 may be sticker tags, inlay/insert tags, or hard tags installed to object transport vehicles 160 and draw power from them. In some embodiments, the system may track tags 180 on freight 120 and on object transport vehicles 160 similarly.

In some embodiments, the plurality of tag readers 170 may be positioned on an elevated location above the warehouse floor, for example, on or near the inside of warehouse ceiling, on columns, beams, or walls of the warehouse, on a standalone post or pole, or on suspended wires above the floor.

In some embodiments, the tag readers 170 may receive signals (e.g., read a tag wirelessly) within a certain angle. Because the tag reader 170 is positioned above the floor, when unobstructed (e.g., by shelves, bays, walls, columns, pipes and other utilities in the warehouse), the tag reader 170 may cover a conical area 190, with the tag reader 170 being at the vertex of a conical area 190. In some embodiments, the angle may be larger than 180 degrees, and even a full 360 degrees. Therefore, the conical area becomes a spherical frustum (i.e., a sphere with the tag reader at the center minus a spherical cap created by the warehouse floor.) In case the angle is larger than 180 degrees but less than 360 degrees, the area 190 below the tag reader is the same as the area 190 in case the angle is a full 360 degrees. In some embodiments, the conical area 190 or the spherical frustum area may be incomplete due to structures of the warehouse (e.g., columns, beams, walls, shelves) blocking some area off. In this disclosure, the area covered by a tag reader 170 may be referred to as a conical area 190, even if it may be a spherical frustrum and/or being incomplete due to other structures' blocking.

In some embodiments, because of the arrangements of the tag readers 170 in the warehouse and/or the conical area 190 being incomplete, the conical areas 190 from adjacent tag readers 170 may overlap or leave a gap that is not covered. Because each tag reader 170 covers a conical area 190, which projects at different height a circle of different size, the overlapping areas and gaps may vary at different elevations. In some embodiments, the projected circles may be overlaid with the floor plan of the warehouse 100 to demonstrate signal coverage of the tag readers 170.

In some embodiments, each of the multiple pieces of freight 120 and object transport vehicles 160 may have a tag 180 attached or affixed to it, and thus associated with the tag 180 through the tag's unique identifier. In some embodiments, the associations between the freight 120 or object transport vehicle 160 and the corresponding tag's unique identifier may be stored on one or more database in the one or more non-transitory memory. In some embodiments, each of the object transport vehicles 160 may have at least two tags 180.

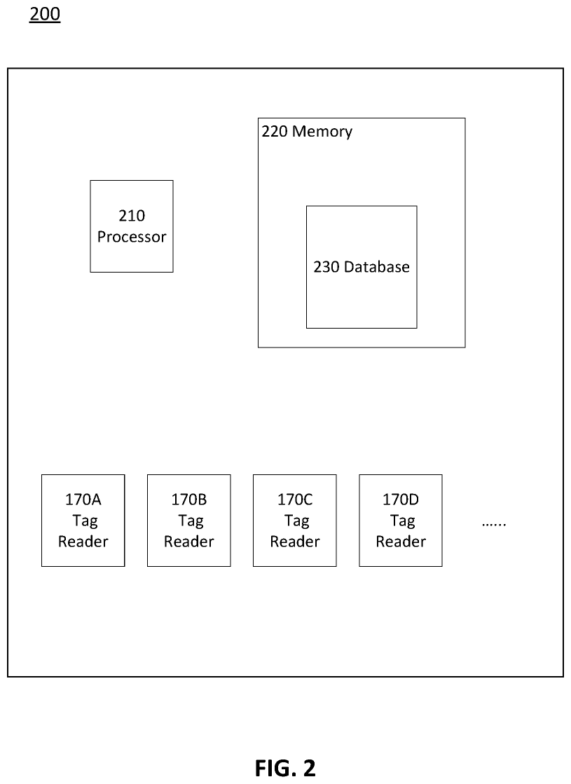

FIG. 2 is a schematic block diagram illustrating an embodiment of a wireless system 200 for tracking object locations, consistent with embodiments of this disclosure. In some embodiments, the system 200 may include at least one processor 210 and at least one non-transitory memory 220 storing instructions, which when executed perform methods for tracking object locations, as described in various embodiments of this disclosure. In some embodiments, the system 200 may also include at least one transitory memory 225 to store temporary information, for example, calculated locations within a preset length of time. In this disclosure, the at least one processor 210 refers to processors in general, and may be processors in a server, a desktop computer, and/or a mobile device (e.g., laptop, smartphone).

The at least one non-transitory memory 220 may refer to non-transitory memory, which retains data even when power is turned off or the system is shut down; the at least one transitory memory 225 may refer to transitory memory, which retains data only while power is supplied to it and loses the data stored in it when the power is turned off. In some embodiments, the non-transitory memory 220 may be hard disk drives (HDDs), Solid-State Drives (SSDs), or flash memory in local or remote servers, or on cloud servers. In some embodiments, the at least one non-transitory memory 220 may be multiple memories on different servers, each memory 220 may perform one or more functions similar or different from other memories 220. In some embodiments, the at least one transitory memory 225 may be Random Access Memory (RAM) or cache memory. In this disclosure, when not specifically distinguished, memory 220 may refer to non-transitory memory 220 or transitory memory 225. In some embodiments, the system 200 may include at least one database 230 stored on memory 220. In some embodiments, the database 230 may store information about the warehouse 100, the multiple pieces of freight 120 being tracked, the object transport vehicles 160 used to move the multiple pieces of freight 120. In some embodiments, the database 230 may include algorithms (e.g., calculation processes, different element weights in averaging calculations, or any other rules and procedures in executing the disclosed methods.)

In some embodiments, the warehouse 100 may have a coordinate system established to describe locations. In some embodiments, the coordinate system may be a 2-dimensional system. In some embodiments, the coordinate system may be a 3-dimensional system. In some embodiments, the coordinate system may be a Cartesian coordinate system with two coordinates (i.e., x-coordinate and y-coordinate) representing the horizontal position on the floor plane and a third coordinate (z-coordinate) representing the vertical position, i.e., height. In some embodiments, other coordinate systems may be adopted.

In some embodiments, the location may also include one or more orientations or directions. For example, a location of an object transport vehicle 160 may include, not only its position in the coordinate system, but also the direction it is facing (e.g., the direction the fork of a forklift is pointing to.) For another instance, the location of an object transport vehicle 160 may also include its moving direction, which is the direction it is moving towards, and may or may not be the same as the direction an object transport vehicle is orienting at. For yet another instance, the location of a tag reader 170 may include its position in the coordinate system, as well as its orientation and angle. In some embodiments, the orientation of a tag reader 170 may indicate a nominal direction (i.e., the center direction of the tag reader's coverage) the tag reader 170 is facing projected on the floor or the warehouse 100. In some embodiments, the angle of a tag reader 170 may be angle between the nominal direction and the horizontal plane (i.e., the floor of the warehouse 100).

In some embodiments, all information of the warehouse 100, for example, floor plan of warehouse 100, grid of zones, locations of tag readers 170 and their conical projections on warehouse floor, locations and moving direction and speed of tags 180, locations and moving directions and speed of object transport vehicles 160, etc. may be stored in a database on the memory 220, either on the non-transitory memory or on the transitory memory as needed and proper. In some embodiments, all information of the warehouse 100 as mentioned above can all overlap because they have coordinates in a same coordinate system. Therefore, system 200 may display all the information as mentioned above all at once on a displaying device (e.g., a monitor, screen, printer, signboard, or other visual system). In some embodiments, system 200 may allow a user to select which information to display on the displaying device.

While an object transport vehicle 160 typically moves on the floor level, in some embodiments, a z-coordinate of the location may indicate the operating height of the object transport vehicle 160. For example, a forklift may move on the warehouse floor, where only x-and y-coordinates are needed for locating the forklift, and its z-coordinate may indicate the height of the fork blades. In other words, the location in the tag read may indicate that the forklift is operating (e.g., loading or unloading objects) at this height. In some embodiments, the tolerances may be dictated by the tag reader specification and use environment (e.g., temperature, humidity, or any other environmental conditions that may impact the data transmission between the tag and the tag reader).

In some embodiments, the z-coordinate of the location may be corrected by the referencing the operating status of the object transport vehicle 160. For example, the processor may consider a separate communication with the forklift reporting its fork blade operating height, and use this information to correct z-coordinate of a corresponding tag read at the same moment.

In some embodiments, information about the warehouse 100 may include the warehouse dimensions, floor plans, ceiling heights, door locations (e.g., dock doors, emergency exits,) tag reader specifications and installation locations, racking and storage system locations and types, climate control (e.g., temperature and humidity control and maps,) security measures (e.g., access control, surveillance locations and capabilities.) In some embodiments, the locations and dimensions may be at least in part using the coordinate system. For example, the information about a door 110 may include its size, location, and open direction, which may be described at least in part through its coordinates (e.g., at least one coordinate for a key point of the door, and/or length of the door, its swinging direction and sweeping area.) In some embodiments, this information may be stored in the at least one memory 220 as coordinate pairs or a set of coordinates. In some embodiments, processor 210 may consider multiple pieces of freight 120 in the warehouse 100 generally as objects being tracked. Because each freight 120 or object transport vehicle 160 has a corresponding tag 180, which has a unique identification, any processor 210 may associate the freight 120 or object transport vehicle 160 and its corresponding tag 180 or tag identification. The database 230 may store associations of tag 180 or tag identifications and their corresponding freight 120 or object transport vehicle 160. In some embodiments, the database 230 may provide the tag-freight/object transport vehicle association to the system 200 for further processing.

In some embodiments, the plurality of tag readers 170A, 170B, 170C, 170D (or collectively, 170 to include all tag readers alike) in the warehouse 100 may receive signals from the tags 180 (i.e., tag reads) wirelessly and transmit the tag reads to the system 200 (e.g., to any processor 210) for processing. In some embodiments, tag reads may refer to this tag 180 to tag reader 170 communication, which may be active or passive, as discussed above.

In some embodiments, the signal may include one or more report of its location and a corresponding time stamp. The one or more report of the tag location from the tag-tag reader communication is referred to as a raw location. In some embodiments, the tag reader 170 may read a tag 180, and calculate multiple locations from the raw locations using different preset algorithms on exact cadence. In some embodiments, the tag reader 170 may publish the reader-calculated locations to different processors according to preset rules. In some embodiments, this reader-calculated location is tag-specific, i.e., the reader-calculated location is a calculated location of the tag 180 and corresponds to single tag reader to tag communication. For example, the tag reader 170 may read a tag 180 and calculate two locations using two different preset algorithms, and publish the reader-calculated locations to different processor 210 for further processing. In some embodiments, the tag reader 170 may include a transitory memory 225 to temporary store tag reads, the raw locations, and the reader-calculated locations.

Similar to the tag reads of the multiple pieces of freight 120, in some embodiments, the plurality of tag readers 170 in the warehouse 100 may read the vehicle tags 180 wirelessly and transmit the tag reads to the system 200 for processing. The tag reads may include one or more report of its location (i.e., raw location) and a corresponding time stamp. The tag reader 170 may similarly calculate multiple reader-calculated locations using different preset algorithms on exact cadence, and publish the reader-calculated locations to different processors according to preset rules.

In some embodiments, the tag reader 170 publishes all reader-calculated locations to the system 200 for processing. The system 200 receives, in the signal, all reader-calculated locations and indications of each of the reader-calculated locations and their corresponding algorithm (e.g., processing windows) and timestamp. Therefore, the system 200 may extract from one or more reader-calculated locations, their corresponding preset algorithm used, and their corresponding time, from one signal.

In some embodiments, processors 210 may process the reader-calculated locations of the tag 180 and query the database 230 for association between the tag identification and the freight 120 or object transport vehicle 160, therefore associate the reader-calculated locations of the corresponding freight 120 or object transport vehicle 160 at the time of the time stamp. In some embodiments, the reader-calculated locations may use the same coordinate system as the warehouse. In some embodiments, each reader-calculated location may have tolerances. In some embodiments, the tolerances may be dictated by the tag reader's specification and use environment (e.g., temperature, humidity, or any other environmental conditions that may impact the data transmission between the tag and the tag reader.)

In some embodiments, the warehouse 100 may have at least one object transport vehicle 160 to move one or more freight 120 in the warehouse 100, i.e., change locations together with the freight 120. The object transport vehicle 160 may also load or unload freight 120, i.e., accept freight 120 into the warehouse 100, or transfer them out of the warehouse 100 (e.g., to truck 195A or airplane 195B). The object transport vehicle 160 may also arrange or rearrange freight 120 inside the warehouse 100, for example, from one storage bay 130 to another, or within a storage bay 130.

In some embodiments, the warehouse 100 may have more than one object transport vehicle 160. Each object transport vehicle 160 may have a tag 180 (i.e., a vehicle tag) associated with it. In some embodiments, each object transport vehicle 160 may have at least two tags 180 associated with it. For example, an object transport vehicle 160 may have a front tag 182 and a back tag 184. By determining locations of both tags 182 and 184, processor 210 may determine the orientation of the object transport vehicle 160. While in this example, the two tags 182 and 184 are placed on the front and the back of the object transport vehicle, a person of ordinary skill would understand that, having two tags placed on any two places of the object transport vehicle 160 would have the same effect and allow the processor 210 to determine the orientation of the object transport vehicle 160.

In some embodiments, vehicle tag for the object transport vehicles 160 may be the same as the tags used for the multiple pieces of freight. In some embodiments, vehicle tag for the object transport vehicles 160 may be different from the tags used for the multiple pieces of freight 120 in form but share a same frequency, so they may all be read, tracked and monitored by the same tag reader 170 in the system 200 at the same time. The database 230 may record the association of the vehicle tags for the object transport vehicles 160 and their corresponding object transport vehicle 160 and provide such association upon request.

In some embodiments, each of the object transport vehicle 160 may have a maximum travel speed. In some embodiments, this maximum travel speed may be dictated by the object transport vehicle's own specification. In some embodiments, system 200 may store the maximum travel speed of an object transport vehicle 160 in the memory 220 and make it available upon inquiry. In some embodiments, different object transport vehicles 160 may have different maximum speeds. For example, there may be object transport vehicles 160 of different make and model, therefore have different maximum speeds. In some embodiments, system 200 may associate the maximum travel speed of a specific object transport vehicle 160 to its identification tag. In some embodiments, when processor 210 generate virtual vehicle tags for virtual object transport vehicles, users may specify the virtual object transport vehicle's make and model to allow processor 210 to properly assign maximum speeds to the virtual tags representing the virtual object transport vehicle. In some embodiments, processors 210 may obtain the virtual object transport vehicle's make and model and assign maximum speeds to the virtual tags representing the virtual object transport vehicle. In some embodiments, processor 210 may directly obtain the maximum speeds of the virtual object transport vehicle and accordingly apply the maximum speeds to the virtual tags representing the corresponding virtual object transport vehicle.

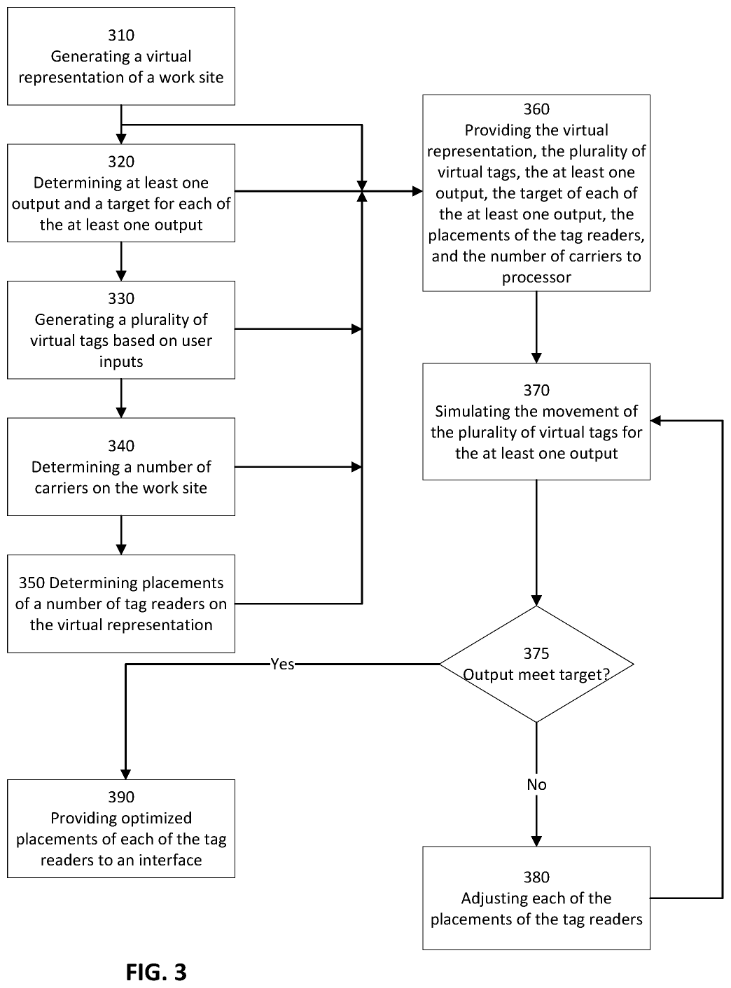

FIG. 3 is a schematic block diagram illustrating an embodiment of a method for simulating a live-event on a work site using a wireless-based tracking system, consistent with embodiments of this disclosure. In some embodiments, the process in FIG. 3 may be executed by one or more of processor 210.

In some embodiments, in step 310, processor 210 may generate a virtual representation of a work site (e.g., a warehouse 100). The virtual representation may be a digitized version of the actual work site. In some embodiments, processor 210 may take user input and use the input to generate the virtual representation. In some embodiments, the user input may include features of the work site and their corresponding coordinates. For example, for a simple rectangular shape work site plan and a single door, user input may include work site dimensions by providing to system 200 the coordinates of the four corners of the work site; user input may also include coordinates of a door, so processor 210 may generate the virtual representation with the door at the right location. A person skilled in the art would understand that the work site may include many more features, and these features can be provided to processor 210 similarly for virtual representation generation purposes. In some embodiments, processor 210 may generate the virtual representation of the work site according to information obtained from database 230.

In some embodiments, processor 210 may generate the virtual representation of the work site combining user input and information obtained from database 230. In some embodiments, information that is saved in database 230 may include data about various aspects of the work site. For example, data about various bays, doors, zones that make up the work site, their locations and sizes; data about tag reader 170 placement, for example, location, orientation, heights; data required for tag reader 170 configurations; or the like. For example, an “tag reader” table may contain data about tag reader placement, orientation, height, and other datapoints needed to configure the tag readers; another “location” table may contain work site specific configuration data. In this example, for this solution to be successful, the location table needs to have an additional set of columns added to store and retrieve ceiling configuration data.

In some embodiments, database 230 may store and maintain the data centrally (e.g., in applications such as Oracle). In some embodiments, processor 210 may mirror data from central database to service centers and may store them in local databases (e.g., Cassandra) of the same names. In some embodiments, database 230 may store the data in a push/pull system, where the data is pushed to database 230 when the data changes, and a separate microservice periodically checks for differences and pulls those missed changes to transitory memory 225 (in case of network/power outages, etc).

In some embodiments, in step 320, processor 210 may determine at least one output and a target for each of the at least one output. In some embodiments, the output may be outcomes related to the objectives of the work site design, and can be either qualitative or quantitative in nature. In some embodiments, the output may be outcomes that has detectable variations for easier direct comparison. For example, the output may be related to the throughput of freight handling in the form of processing time, or average time freights stay on the work site. Using time as an outcome is measurable and directly comparable. For another example, the output may be related to a heatmap of work site congestion, which illustrate the frequencies of object transport vehicle 160 showing up. In some embodiments, a heatmap of work site congestion may identify high traffic areas that may need to be reworked and optimized. For another example, the output may be related to utilization rate of object transport vehicle 160. In some embodiments, the utilization rate of an object transport vehicle 160 is the percentage of time during which the object transport vehicle 160 is carrying an object 120. The utilization rate may be an indication of operating efficiency.

In some embodiments, processor 210 may transcribe qualitative outcomes into scores or ratings before being used as an output. For example, satisfaction is a qualitative outcome and may be, for example, different verbiage, such as “not at all satisfied,” “not satisfied,” “neither satisfied nor dissatisfied,” “somewhat satisfied,” and “very satisfied.” Processor 210 can first transform satisfaction into ratings of 1 to 5 (e.g., 1 being “not at all satisfied” and 5 being “very satisfied”) before using it as an outcome with numerical ratings that can be further calculated, compared, and analyzed.

In some embodiments, each selected outcome may have a target. The target may be determined by the user, reflecting the goal of the work site design. In some embodiments, the target is constrained by real world implications. For example, the outcome of average time freights stay on the work site must be a positive number.

In some embodiments, in step 330, processor 210 may generate a plurality of virtual tags based on user inputs. In some embodiments, instead of registering tag 180 through signals received by tag readers 170, user may instruct processor 210 to generate and register virtual tags. In some embodiments, processors may display the virtual tags according to its corresponding coordinates on the displaying device. In some embodiments, processor 210 may put virtual tags and tags 180 on the displaying device in a same way. In some embodiments, processor 210 may display and move virtual tags accordingly to preset rules. In some embodiments, the preset rules may be so that the virtual tags move in a manner very similar to actual physical tags 180 would move and be read by tag readers 170. In other words, virtual tags are fake tags. In the eyes of an user watching from the displaying device, virtual tags may look like actual physical tags 180, and behave like one, too.

In some embodiments, user may instruct processor 210 to generate certain number of virtual tags. In some embodiments, user may instruct processor 210 to generate virtual tags with a changing quantity subject to a set of preset rules. For example, user may instruct processor 210 to first generate a number of virtual tags, then increase the number of virtual tags to a maximum number when certain conditions are met. In some embodiments, user may instruct processor 210 to increase the number of virtual tags until certain preset conditions are met. For example, user may instruct processor 210 to increase the number of virtual tags until the average time freights stay on the work site exceeds a preset time. This may effectively be a stress test for the work site design.

In some embodiments, in step 340, processor 210 may determine a number of virtual object transport vehicles on the work site for the simulation, the number of virtual object transport vehicles is corresponds to the number of actual object transport vehicles 160 that is on the work site or being planned to deploy on the work site. Processor 210 may determine how many virtual object transport vehicles are there on the work site. In some embodiments, a user may provide input to system 200 on the number of virtual object transport vehicles on the work site.

In some embodiments, the number of object transport vehicles on the work site 100 may be adjusted from time to time. In some embodiments, the user may set rules on the number of virtual object transport vehicles may change. For example, the user may instruct processor 210 to take each virtual object transport vehicle offline every preset amount of time to simulate the object transport vehicle going through servicing/maintenance, thus reducing the number of virtual object transport vehicles by one. In some embodiments, the user may instruct processor 210 to randomly simulate object transport vehicle down time due to malfunctioning/repairing. In some embodiments, the frequency of maintenance and probability of malfunctioning may be determined from historical data and/or equipment specification or be provided by the manufacturer of the object transport vehicles.

In some embodiments, in step 350, processor 210 may determine placements of a number of tag readers (e.g., antennas) on the virtual representation. In some embodiments, the placement of a tag reader 170 refers to the installation location of the tag reader 170, and may include the position of the tag reader 170 in the coordinate system, as well as its orientation and angle. In some embodiments, the placement of a tag reader 170 may include its location, orientation, and angle. In some embodiments, the location of a tag reader 170 may be in the form of coordinates. In some embodiments, the orientation of a tag reader 170 may indicate a nominal direction (i.e., the center direction of the tag reader's coverage) the tag reader 170 is facing projected on the floor or the warehouse 100. In some embodiments, the angle of a tag reader 170 may be angle between the nominal direction and the horizontal plane (i.e., the floor of the warehouse 100).

In some embodiments, processor 210 may determine the number of tag readers 170 before determining their respective placement. In some embodiments, a user may provide input on both the number of tag readers 170 and their respective placement.

In some embodiments, processor 210 may determine the placements of the tag readers on the virtual representation by initially evenly (e.g., uniformly) spreading them out on the virtual representation. In some embodiments, tag readers 170 may be placed in a honeycomb pattern to maximize covered areas. In some embodiments, processor 210 may start the placement by placing the first tag reader 170 at the door of the work site as (0,0), and space the next tag readers 170 in a honeycomb pattern to fill the space of the work site in a way that maximize the covered area. In some embodiments, the tag readers 170 collectively cover at least a part of the work site 100 and are configured to receive signals from the object transport vehicles and the tags 180 in the covered area. In some embodiments, processor 210 may determine placement of the tag readers 170 following instructions of a user. In some embodiments, processor 210 may determine the placements of the tag readers on the virtual representation by further adjusting the tag readers' placements considering preset rules. In some embodiments, the preset rules may include real world constraints from the work site structure, building codes, local bylaws, etc. In some embodiments, processor 210 may determine to end the adjustments when processor 210 determine that certain goals are met. In some embodiments, the goals are related to the type of simulation. For example, for performance tests, the test run time may vary again depending on whether the goal of test is to determine maximum throughput, identify memory leaks, etc. In some embodiments, the endpoint of the adjustment may also be any predefined event.

In some embodiments, in step 360, processor 210 may provide the virtual representation, the plurality of virtual tags, the at least one output, the target of each of the at least one output, the placements of the number of tag readers, and the number of object transport vehicles to the at least one processor. In some embodiments, upon receiving these pieces of information, processor 210 may further provide placements of the virtual tags on the virtual representation of the work site 100 to simulate the work site 100 as an operating warehouse 100 with object transport vehicles 160 moving freights 120. In other words, processor 210 may use the information provided to simulate a real-world scenario where tag readers 170 receive signals from tags 180 affixed/installed on object transport vehicles 160 and freights 120.

Because the virtual tags are fake tags generated in batches, providing them to processor 210 requires different processes compared to providing signals from real tags 180. In some embodiments, providing the plurality of virtual tags to the at least one processor may include multiple steps. In some embodiments, processor 210 may subdivide the plurality of virtual tags to a plurality of lists. In some embodiments, processor 210 may then assign each of the plurality of publishing entities exclusively to one of the plurality of lists. In some embodiments, dividing the plurality of virtual tags into lists may be based on tag readers (i.e., dividing actual or virtual signals by tag reader 170). In some embodiments, such divisions may increase throughput while ensuring that each tag reader's signals (e.g., actual and virtual) may be published at an appropriate time in a narrow timeframe without having unrelated signals queueing in between.

In some embodiments, for each of the plurality of publishing entities, processor 210 may then publish the corresponding list that is assigned to it. In some embodiments, having the plurality of publishing entities for the publishing of the plurality of virtual tags may increase the volume of signals that processor 210 may publish within a given timeframe.

In some embodiments, in step 370, processor 210 may simulate the movement of the plurality of virtual tags for the at least one output. In some embodiments, processor 210 may assign to each of the plurality of virtual tags a movement rule. For example, processor 210 may assign to a virtual tag to be a freight to be moving from one location to another location; processor 210 may assign another two virtual tags to be the front and back tag of an object transport vehicle assigned to transport the freight. Processor 210 may then simulate the movement of the virtual vehicle tags to first move to the freight tag, then move with the freight tag to the destination of the freight tag. In some embodiments, the speed of these movement may be constrained and limited to be no faster than the maximum moving speed of the object transport vehicle. In this disclosure, vehicle tags may refer to both the actual physical tags attached to an object transport vehicle and virtual tags generated by processor 210 that move under the same rules and restrictions of actual physical tags attached to an object transport vehicle, for the purposes of simulation.

In some embodiments, the movement of the plurality of virtual tags is constrained by the work site. For example, the work site 100 may have a column at a certain location, so when the virtual tags are moving during the simulation, they will avoid moving into the column.

In some embodiments, the movement of the virtual tags and the vehicle tags on the virtual representation of the work site 100 may be in a way consistent with tag 180 being able to be tracked by the tag readers 170. In some embodiments, when the virtual tags are moving with the virtual vehicle tags, processor 210 may determine whether their locations on the virtual representation correspond to trackable locations on the actual work site with the placements of the tag readers 170. In some embodiments, processor 210 may design the movement to be within the area covered by the plurality of tag readers 170. In some embodiments, processor 210 may allow a part of the trip to be outside the area covered by the tag readers 170. In some embodiments, the part of the trip can be measured by percentage of total trip, or less than a threshold time either consecutively or in total, or less than a threshold distance either consecutively or in total. For example, processor 210 may consider a trip trackable if the route includes several short periods of time, in which the virtual tag would be in an area not covered by the plurality of tag readers 170, and none of the short periods of time is longer than one second. In some embodiment, the time threshold may be one second, two second, five second, or any time threshold dictated by tag reader capability. In some embodiments, the distance threshold may be one meter, two meters, five meters, or any distance dictated by tag reader capability and object transport vehicle maximum speed.

In some embodiments, processor 210 may determine that a virtual tag cannot be moved successfully if there is no acceptable route to move it from its current location to its assigned destination, and thus mark the virtual tag as undeliverable. In some embodiments, processor 210 may determine a work site design not operable if more than a preset number of virtual tags have an undeliverable marker.

In some embodiments, processor 210 may arrange the virtual vehicle tags to simulate delivering multiple virtual tags either simultaneously or sequentially. In some embodiments, processor 210 may arrange virtual vehicle tags to move without a virtual tag after transporting a virtual tag to its destination.

In some embodiments, processor 210 may simulate different types of tag movements under different rules. In some embodiments, the different types of tag movements may include, at least, from a door to a bay, from a bay to a door, from a door to a door, and from a bay to a bay. In some embodiments, the tag 180 (e.g., virtual and actual) should move with a tag of an object transport vehicle. In some embodiments, processor 210 may design a route for the tags to move along the perimeter of the warehouse 100 as much as possible. In some embodiments, the perimeter of the warehouse 100 may not have freight 120 stored and thus may allow faster travel and quicker maneuver of object transport vehicles 160. In some embodiments, processor 210 may assign a percentage chance to each movement type that the movement deviate from a designed route. In some embodiments, the percentage chance may be different for each movement type. In some embodiments, processor 210 may assign a percentage chance that a small amounts of tags 180 (e.g., virtual and actual) may move together. In some embodiments, the small amount may be one to three. In some embodiments, the small amount may be less than five. In some embodiments, the small amount may be less than 10.

In some embodiments, in step 380, processor 210 may iteratively adjust each of the placements of the number of tag readers (e.g., antennas) to optimize at least one output towards the targets of the at least one output. In some embodiments, processor 210 may bring two adjacent tag readers closer to close a gap of the tag readers' coverage or improve coverage of certain location. In some embodiments, processor 210 may space apart two adjacent tag readers to reduce overlapping areas of two tag readers' coverage. In some embodiments, processor 210 may space out two adjacent tag readers even when their coverages are not overlapping and have a gap, in a balanced consideration of operating efficiency. For example, processor 210 may determine that a gap between two covered areas may increase while the object transport vehicle travel time in the gap remains below the threshold time (i.e., a direct travel through the gap is still considered as acceptable.)

In some embodiments, when adjusting the placement of the antennas, processor 210 may be under some present constraints. In some embodiments, such constraints may include real world constraints, such as real estate deeds, government regulations (e.g., building codes, safety regulations), equipment (e.g., forklifts, antennas) capabilities, or cost. For example, each additional forklift may require a certain budget to operate, the cost of adding each additional forklift may include, for example, human capital cost, cost of purchasing and maintaining, etc. For another example, each additional tag reader (i.e., antenna) may have a cost of purchasing, a cost of installation, and a cost of operation. In some embodiments, some cost may be one time cost to set-up or purchase, while some cost may be operational or ongoing cost.

In some embodiments, after adjusting each of the placements of the number of tag readers, processor 210 may repeat step 370 and compare the result with previous results in step 375. In some embodiments, processor 210 may iteratively repeat steps 370, 375, and 380 until the simulation output meets its preset target. In some embodiments, processor 210 may repeat steps 370, 375, and 380 until all the outputs meet their respective target. In some embodiments, processor 210 may repeat steps 370, 375, and 380 until results converge to their best possible outcome, regardless of whether the targets are met. In such cases, processor 210 may inform user that not all targets can be met at the same time and request target adjustment.

In some embodiments, in step 390, processor 210 may provide optimized placements for each of the placements of the tag readers to an interface. In some embodiments, processor 210 may recommend the placements of the tag readers based on the optimized placements. In some embodiments, processor 210 may inform the user the outcomes, and whether they meet their respective target. In some embodiments, processor 210 may inform the user that the system 200 may not find a viable solution and recommend adjustment of user inputs, as outlined in steps 310-350.

Computer programs based on the written description and disclosed methods are within the skill of an experienced developer. Various programs or program modules can be created using any of the techniques known to one skilled in the art or can be designed in connection with existing software. For example, program sections or program modules can be designed in or by means of.Net Framework,.Net Compact Framework (and related languages, such as Visual Basic, C, etc.), Java, C++, Objective-C, HTML, HTML/AJAX combinations, XML, HTML with included Java applets, or Golang.

Moreover, while illustrative embodiments have been described herein, the scope of any and all embodiments having equivalent elements, modifications, omissions, combinations (e.g., of aspects across various embodiments), adaptations and/or alterations as would be appreciated by those skilled in the art based on the present disclosure. The limitations in the claims are to be interpreted broadly based on the language employed in the claims and not limited to examples described in the present specification or during the prosecution of the application. The examples are to be construed as non-exclusive. Furthermore, the steps of the disclosed methods may be modified in any manner, including by reordering steps and/or inserting or deleting steps. It is intended, therefore, that the specification and examples be considered as illustrative only, with a true scope and spirit being indicated by the following claims and their full scope of equivalents.

What is claimed is:

1. A system for simulating an operational scenario on a work site using a wireless-based tracking system comprising at least one processor, the system comprising:
at least one processor; and
at least one non-transitory memory storing instructions, when executed by the at least one processor, perform steps of:
generating a virtual representation of a work site, the work site comprising at least one door and a plurality of zones;
determining at least one output and a target for each of the at least one output;
generating a plurality of virtual tags based on user inputs;
determining a first number of object transport vehicles on the work site;
determining placements of a second number of antennas on the virtual representation, wherein the antennas collectively cover at least a part of the work site and are configured to receive signals from the first number of object transport vehicles and the plurality of virtual tags in the covered part of the work site;
providing the virtual representation, the plurality of virtual tags, the at least one output, the target of each of the at least one output, the placements of the second number of antennas, and the first number of object transport vehicles to the at least one processor;
simulating a movement of the plurality of virtual tags for the at least one output, wherein the plurality of virtual tags are moved with the at least one of the first number of object transport vehicles and tracked by the antennas;
iteratively adjusting each of the placements of the second number of antennas to optimize at least one output towards the targets of the at least one output; and
providing optimized placements for each of the placements of second number of antennas to an interface.

2. The system of claim 1, wherein the movement of the plurality of virtual tags is constrained by the work site.

3. The system of claim 1, wherein the work site has a layout of an n-point polygon.

4. The system of claim 3, wherein a ceiling height follows a linear slope from the center of the n-point polygon to each edges of the n-point polygon.

5. The system of claim 1, wherein each of the placements of the second number of antennas comprises an antenna location, an antenna orientation, and an antenna angle.

6. The system of claim 1, wherein each of the first number of object transport vehicles has an identification tag, a maximum travel speed, and an object transport vehicle location associated with the corresponding object transport vehicle.

7. The system of claim 1, wherein providing the plurality of virtual tags comprises:
subdividing the plurality of virtual tags to a plurality of lists;
creating a plurality of publishing entities;
assigning each of the plurality of publishing entities exclusively to one of the plurality of lists;
for each of the plurality of publishing entities, publishing the corresponding list.

8. The system of claim 1, wherein iteratively adjusting each of the placements of the second number of antennas is under preset constraints comprising at least one of:
real estate deeds;
government regulations;
equipment capability; or
cost.

9. The system of claim 8, wherein the government regulations comprise building codes or safety regulations.

10. The system of claim 8, wherein the equipment capability comprises capabilities of each of the plurality of the antennas of the work site or the capabilities of additional equipment being used in the work site.

11. A method of simulating an operational scenario on a work site using a wireless-based tracking system comprising at least one processor, the method comprising:
generating a virtual representation of a work site, the work site comprising at least one door, a plurality of zones;
determining at least one output and a target for each of the at least one output;
generating a plurality of virtual tags based on user inputs;
determining a first number of object transport vehicles on the work site;
determining placements of a second number of antennas on the virtual representation, wherein the antennas collectively cover at least a part of the work site and are configured to receive signals from the first number of object transport vehicles and the plurality of virtual tags in the covered part of the work site;
providing the virtual representation, the plurality of virtual tags, the at least one output, the target of each of the at least one output, the placements of the second number of antennas, and the first number of object transport vehicles to the at least one processor;
simulating a movement of the plurality of virtual tags for the at least one output, wherein the plurality of virtual tags are moved with the at least one of the first number of object transport vehicles and tracked by the antennas;
iteratively adjusting each of the placements of the second number of antennas to optimize at least one output towards the targets of the at least one output; and
providing optimized placements for each of the placements of the second number of antennas to an interface.

12. The method of claim 11, wherein the movement of the plurality of virtual tags is constrained by the work site.

13. The method of claim 11, wherein the work site has a layout of an n-point polygon.

14. The method of claim 13, wherein a ceiling height follows a linear slope from the center of the n-point polygon to each edges of the n-point polygon.

15. The method of claim 11, wherein each of the placements of the second number of antennas comprises an antenna location, an antenna orientation, and an antenna angle.

16. The method of claim 11, wherein each of the first number of object transport vehicles has an identification tag, a maximum travel speed, and an object transport vehicle location associated with the corresponding object transport vehicle.

17. The method of claim 11, wherein providing the plurality of virtual tags comprises:
subdividing the plurality of virtual tags to a plurality of lists;
creating a plurality of publishing entities;
assigning each of the plurality of publishing entities exclusively to one of the plurality of lists;
for each of the plurality of publishing entities, publishing the corresponding list.

18. The method of claim 11, wherein iteratively adjusting each of the placements of the second number of antennas is under preset constraints comprising at least one of:
real estate deeds;
government regulations;
equipment capability; or
cost.

19. The method of claim 18, wherein the government regulations comprise building codes or safety regulations.

20. The method of claim 18, wherein the equipment capability comprises capabilities of each of the plurality of the antennas of the work site or the capabilities of additional equipment being used in the work site.
